(19) United States
(12) Patent Application Publication
(10) Pub. No.: US 2025/0234784 A1
(43) Pub. Date: Jul. 17, 2025

(54) PHOTODETECTOR BASED ON TRANSVERSE DEMBER EFFECT AND PREPARATION METHOD THEREOF

(71) Applicant: Heatex Sensing Technology (Huzhou) Co., Ltd., Huzhou City (CN)

(72) Inventors: Yong WANG, Huzhou City (CN); Yahui HUANG, Huzhou City (CN); Kunlun WANG, Huzhou City (CN); Yan ZHANG, Huzhou City (CN)

(21) Appl. No.: 18/925,210

(22) Filed: Oct. 24, 2024

(30) Foreign Application Priority Data
Jan. 11, 2024 (CN) 202410037938.4

(51) Int. Cl. H10N 15/10

(52) U.S. Cl. CPC H10N 15/15

(57) ABSTRACT

Provided is a photodetector based on transverse Dember effect and a preparation method. The method includes: growing a tilted epitaxial layer on a tilted single-crystal substrate; preparing a patterned metal electrode pair on an upper surface of the tilted epitaxial layer; and connecting each metal electrode to one end of a metal wire via high temperature silver glue, and connecting the other end of the metal wire to a voltage signal acquisition device. There is an included angle between a crystallographic axis and a normal of the tilted epitaxial layer. Photoelectric detection with high responsivity is implemented by means of transverse Dember effect of the tilted epitaxial layer, which resolves problems of an existing photodetector such as a bias voltage needs to be applied, operations are complex, stability is poor, sensitivity is low, and the existing photodetector is easy to be interfered with an environment.

### CROSS REFERENCE TO RELATED APPLICATION

This patent application claims the benefit and priority of Chinese Patent Application No. 202410037938.4, filed with the China National Intellectual Property Administration on Jan. 11, 2024, the disclosure of which is incorporated by reference herein in its entirety as part of the present application.

### TECHNICAL FIELD

The present disclosure relates to the technical field of semiconductor photodetectors, and in particular to a photodetector based on transverse Dember effect and a preparation method thereof.

### BACKGROUND

When light is incident into a detector, photons excite electrons in materials of the detector, thereby generating charge carriers. The charge carriers are collected and converted into an electrical signal, to implement detection on the light. At present, photodetectors are widely used in the fields of ultraviolet detection, ultraviolet imaging, spectral analysis, medical diagnostics, and the like. Existing photodetectors include a diode (including a PN junction and a Schottky junction)-based photodetector and a photodetector based on transverse thermoelectric effect. When the diode-based photodetector is used to test laser intensity, photon energy is absorbed by a semiconductor, to excite carriers in the semiconductor. An electric field is formed in a space charge region by applying an appropriate bias voltage, and excited electrons in the electric field across the space charge region enter a neighboring metal or a semiconductor region. In this process, the carriers move to form photoelectric currents. A magnitude of the photoelectric current is related to the laser intensity, and thus information about the laser intensity can be obtained by measuring the photoelectric currents. The diode-based photodetector is a current-type device, and has a poor anti-interference capability in comparison with a voltage-type device. In addition, a bias voltage needs to be applied during testing, which increases complexity of operations and power consumption of the device. Further, the diode-based photodetector is only suitable for low-power laser testing. The photoelectric currents are easy to be saturated once optical power density is high. When laser irradiates an upper surface of a film, a temperature gradient is formed on an upper surface and a lower surface of the photodetector based on transverse thermoelectric effect, thereby generating a voltage signal on the upper surface of the film. Sensitive detection on laser power is implemented by measuring a transverse electric field caused by the temperature gradient. The photodetector based on transverse thermoelectric effect is a voltage-type device, but sensitivity is low, and noise is large. Under large laser power density of irradiation, if heat is not dissipated timely, a direction of the temperature gradient of the upper surface and the lower surface of the film is easy to be changed. This enables polarity of a transverse thermoelectric voltage signal to be reversed, that is, a positive voltage is changed to a negative voltage. As a result, a measurement error is large. In addition, a signal of transverse thermoelectric effect is easy to be affected by an ambient temperature. A change in the temperature leads to fluctuation of the signal of the transverse thermoelectric effect, and thus accuracy of the measurement is affected.

### SUMMARY

In view of the problems in the background, the present disclosure provides a photodetector based on transverse Dember effect and a preparation method thereof, to implement passive photoelectric detection in a manner of high stability, high sensitivity, and simple operations.

To achieve the above objective, the present disclosure provides the following technical solutions.

According to one aspect, the present disclosure provides a photodetector based on transverse Dember effect. The photodetector based on transverse Dember effect includes: a tilted single-crystal substrate, a tilted epitaxial layer, a metal electrode pair, metal wires, and a voltage signal acquisition device. The tilted epitaxial layer is located on an upper surface of the tilted single-crystal substrate; a tilt angle of the epitaxial layer is an included angle between a crystallographic axis and a surface normal of the epitaxial layer; two metal electrodes of the metal electrode pair are respectively located at two ends of an upper surface of the tilted epitaxial layer; each metal electrode is connected to one metal wire; the voltage signal acquisition device is configured to acquire voltage signals output by the two metal wires; and the voltage signals are generated by means of transverse Dember effect of the tilted epitaxial layer.

Optionally, the tilt angles range from 0.1° to 45°.

Optionally, a material of the tilted single-crystal substrate is AlN, Si₃N₄, or 4H-SiC.

Optionally, a material of the tilted epitaxial layer is Ga₂O₃, GaN, AlN, BN, B₄C, AlP, or 4H-SiC.

Optionally, a thickness of the tilted epitaxial layer is from 10 nm to 50,000 nm.

Optionally, a thickness of the metal electrode pair is from 50 nm to 200 nm; and a material of the metal electrode pair is W, Ag, Ti, Ni, or Pt.

Optionally, the metal wire is a high-purity metal wire.

According to another aspect, the present disclosure further provides a method for preparing a transverse Dember effect-based photodetector. The method includes: growing a tilted epitaxial layer on a tilted single-crystal substrate using a vapor deposition method, where there is an included angle between a crystallographic axis and a normal of the tilted epitaxial layer, and tilt angles of the tilted single-crystal substrate and the tilted epitaxial layer are quite close; preparing a patterned metal electrode pair on an upper surface of the tilted epitaxial layer, where two metal electrodes of the patterned metal electrode pair are respectively located at two ends of the upper surface of the tilted epitaxial layer; and connecting each metal electrode to one end of a metal wire via high temperature silver glue, and connecting the other end of the metal wire to a voltage signal acquisition device.

Optionally, the growing a tilted epitaxial layer on a tilted single-crystal substrate using a vapor deposition method specifically includes: growing a tilted single-crystal epitaxial film on the tilted single-crystal substrate using a chemical vapor deposition method, taking the tilted single-crystal epitaxial film as the tilted epitaxial layer, where a thickness of the tilted epitaxial layer is from 10 nm to 50,000 nm; and the tilt angles of the tilted single-crystal substrate and the tilted epitaxial layer range from 0.1° to 45°.

Optionally, the preparing a patterned metal electrode pair on an upper surface of the tilted epitaxial layer specifically includes: placing the tilted single-crystal substrate of the tilted epitaxial layer into a radio frequency magnetron sputtering device for vacuumization, and sputtering the patterned metal electrode pair on the upper surface of the tilted epitaxial layer in combination with a mask plate.

According to specific embodiments provided in the present disclosure, the present disclosure has the following technical effect.

The present disclosure provides the photodetector based on transverse Dember effect and the preparation method thereof. The method includes: growing a tilted epitaxial layer on a tilted single-crystal substrate; preparing a patterned metal electrode pair on an upper surface of the tilted epitaxial layer; and connecting each metal electrode to one end of a metal wire via high temperature silver glue, and connecting the other end of the metal wire to a voltage signal acquisition device. There is an included angle between a crystallographic axis and a surface normal of the tilted epitaxial layer. Photoelectric detection with high responsivity is implemented by means of transverse Dember effect of the tilted single-crystal substrate and the tilted epitaxial layer, which resolves problems of an existing photodetector such as a bias voltage needs to be applied, operations are complex, stability is poor, sensitivity is poor, and the existing photodetector is easy to be interfered with an environment. In the present disclosure, the photodetector based on transverse Dember effect generates a voltage signal under light illumination. Compared with a current signal, stability is better; and compared with a photodetector based on transverse thermoelectric effect, sensitivity is higher. Therefore, photoelectric detection in a complex environment can be realized.

### BRIEF DESCRIPTION OF THE DRAWINGS

To describe the technical solutions in embodiments of the present disclosure or in the prior art more clearly, the accompanying drawings required for embodiments are briefly described below. Apparently, the accompanying drawings in the following description show merely some embodiments of the present disclosure, and those of ordinary skill in the art may still derive other accompanying drawings from these accompanying drawings without creative efforts.

FIG. 1 is a front view of a photodetector based on transverse Dember effect according to the present disclosure;

FIG. 2 is a top view of a photodetector based on transverse Dember effect according to the present disclosure;

FIG. 3 is a diagram of test results of transverse Dember voltages under different optical power density according to an embodiment of the present disclosure; and

FIG. 4 is a linear relationship between different optical power density and transverse Dember voltages of a photodetector based on transverse Dember effect according to embodiment of the present disclosure.

### DETAILED DESCRIPTION OF THE EMBODIMENTS

The technical solutions of embodiments of the present disclosure are clearly and completely described below with reference to the drawings in embodiments of the present disclosure. Apparently, the described embodiments are merely a part rather than all of embodiments of the present disclosure. All other embodiments obtained by a person of ordinary skill in the art based on embodiments of the present disclosure without creative efforts shall fall within the protection scope of the present disclosure.

A diode-based photodetector is a current-type device, has a poor anti-interference capability and complex tests in comparison with a voltage-type device. A photodetector based on the transverse thermoelectric effect is a voltage-type device, and has low sensitivity. In addition, a signal of transverse thermoelectric effect is strongly affected by an ambient temperature, and thus accuracy of measurement is affected. Based on this, the present disclosure provides a photodetector based on transverse Dember effect (TDE) and a preparation method thereof, to implement passive photoelectric detection in a manner of high stability, high sensitivity, and simple operations.

In order to make the above objective, features and advantages of the present disclosure clearer and more comprehensible, the present disclosure will be further described in detail below in combination with accompanying drawings and particular implementation modes.

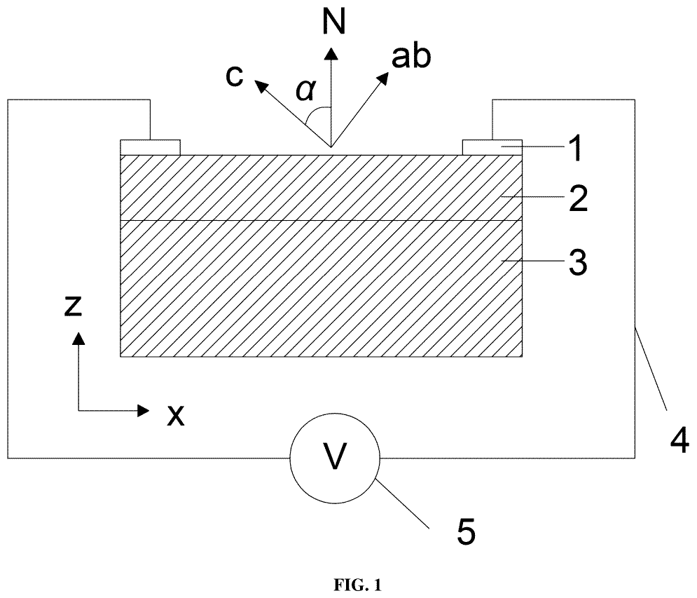

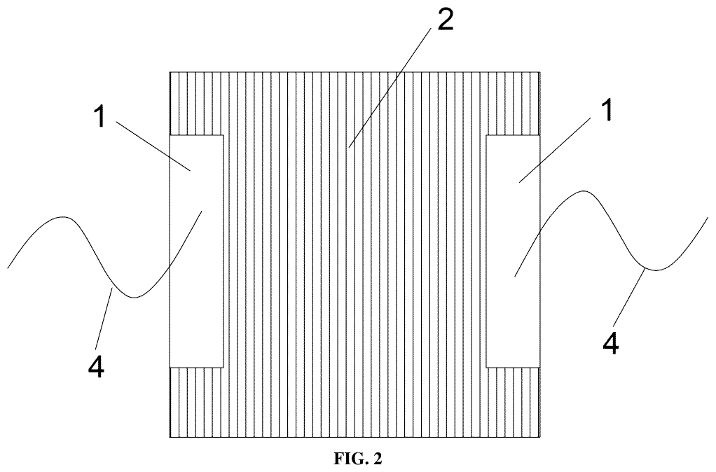

FIG. 1 and FIG. 2 are respectively a front view and a top view of a photodetector based on transverse Dember effect according to the present disclosure. Referring to FIG. 1 and FIG. 2, the photodetector based on transverse Dember effect provided in the present disclosure includes: a tilted single-crystal substrate 3, a tilted epitaxial layer 2, a metal electrode pair 1, metal wires 4, and a voltage signal acquisition device 5. A lattice of a crystal may be regarded as a three-dimensional coordinate system that includes three mutually perpendicular coordinate axes (generally represented by an a-axis, a b-axis, and a c-axis). The c-axis is in a direction of a developing crystal edge, that is, a crystallographic axis; and an ab-plane is a plane perpendicular to the c-axis. An x-axis and a z-axis in FIG. 1 are both a three-dimensional coordinate axis with conventional meaning. N represents a surface normal of the tilted epitaxial layer 2.

Specifically, the tilted epitaxial layer 2 is disposed on an upper surface of the tilted single-crystal substrate 3. A tilt angle of the epitaxial layer 2 is an included angle α between the crystallographic axis c-axis and the surface normal N of the tilted epitaxial layer 2. That is to say, tilting of the tilted epitaxial layer 2 in the present disclosure means that there is the included angle α between the crystallographic axis c-axis and the normal N, and α is from 0.1° to 45°.

Referring to FIG. 1 and FIG. 2, two metal electrodes of the metal electrode pair 1 are respectively located at the two ends of the upper surface of the tilted epitaxial layer 2; and each metal electrode is connected to one metal wire 4. The voltage signal acquisition device 5 is configured to acquire voltage signals output by the two metal wires 4; and the voltage signals are generated by means of transverse Dember effect of the tilted epitaxial layer 2.

In some embodiments, for the tilted single-crystal substrate 3, the tilt angle is from 0.1° and 45°, and a material is AlN (0001), Si₃N₄ (001), or 4H-SiC.

In some embodiments, a material of the tilted epitaxial layer 2 is Ga₂O₃, GaN, AlN, BN, B₄C, AlP, or 4H-SiC. The tilt angle of the tilted epitaxial layer 2 is consistent with the tilt angle of the tilted single-crystal substrate 3, and a tilted single-crystal epitaxial film grown on the tilted single-crystal substrate is taken as the tilted epitaxial layer 2.

In some embodiments, a thickness of the tilted epitaxial layer 2 is from 10 nm to 50,000 nm. The thickness is a vertical distance from an upper surface to a lower surface of the tilted single-crystal epitaxial film.

In some embodiments, a patterned metal electrode pair 1 is prepared on the upper surface of the tilted epitaxial layer 2. A thickness of the metal electrode is from 50 nm to 200 nm, and a material of the metal electrode may be W, Ag, Ti, Ni, or Pt. The two metal electrodes of the metal electrode pair 1 are respectively located at the two ends of the tilted epitaxial layer 2, the metal electrodes are generally rectangular (but are not limited to rectangles), and each metal electrode is connected to one metal wire 4.

In some embodiments, the metal wire 4 is a high-purity metal wire, for example, a silver wire.

In some embodiments, the voltage signal acquisition device 5 may use an oscilloscope, a source meter, or the like.

In the present disclosure, the tilted epitaxial layer 2 that has a specific included angle α (0.1°<α<) 45° with the crystallographic axis c-axis is grown on the tilted single-crystal substrate 3. A graphical design is conducted via a mask plate, and the metal electrode pair 1 is sputtered on the upper surface of the tilted epitaxial layer 2. One end of the metal wire 4 is connected to the metal electrode with silver glue, and the other end of the metal wire 4 is connected to the voltage signal acquisition device 5. The voltage signal acquisition device 5, for example, the oscilloscope, the source meter, or the like may acquire a transverse Dember voltage.

When laser irradiates on an upper surface of a tilted epitaxial layer 2 in a middle region of the metal electrode shown in FIG. 2, energy of photons is greater than a width of a band gap of a semiconductor, and electron-hole pairs are generated due to irradiation of the photons. There is a significant difference in mobility or a diffusion rate of electrons and holes along a tilted direction. Therefore, a wavelength and intensity of the laser can be obtained based on a transverse Dember voltage signal that is detected at two ends of the metal electrode by the voltage signal acquisition device 5 and in combination with a calibration result of the photodetector based on transverse Dember effect.

Specifically, when the energy of the photons is larger than the value of the band gap of the semiconductor, there is a significant difference between the mobility or diffusion rate of the electrons and holes generated by the irradiation of the photons in the semiconductor, resulting in a potential difference in a light illumination direction. When the upper surface of the tilted epitaxial layer 2 is irradiated by light, the electron-hole pairs generated by the photons diffuse from an irradiated side to the other side, while an internal electric field is generated due to the difference between the mobility or the diffusion rate of the electrons and the holes. Therefore, in combination with an Einstein relation, an expression of the voltage signal generated based on transverse Dember effect is as follows:

$${V}_{u} = \frac{{k}_{B} T Δ nl sin 2 α}{2 nde} ( \frac{{μ}_{ab}^{p}}{{μ}_{ab}^{n}} - \frac{{μ}_{c}^{p}}{{μ}_{c}^{n}} ) . \qquad ( 1 )$$

Vᵤ represents the transverse Dember voltage, k_{B} represents a Boltzmann constant, T represents an absolute temperature; Δn represents a concentration difference between carriers (electrons) on the upper surface and the lower surface of the tilted epitaxial layer 2, that is, photo-generated carriers; l represents a light illumination length; α represents the tilt angle of the tilted epitaxial layer 2; n represents density of electrons of the semiconductor before irradiation; d represents a thickness of the film, and e represents charges of the carriers; μ_{ab}^{p}, μ_{c}^{p} respectively represent mobility of the holes along the ab-plane and the c-axis; and μ_{ab}ⁿ, μ_{c}ⁿ respectively represent mobility of the electrons along the ab-plane and the c-axis.

It can be learned from the expression (1) of transverse Dember effect, a transverse voltage Vᵤ generated based on transverse Dember effect is proportional to the concentration Δn of photo-generated carriers, while power/energy of incident light is directly proportional to the concentration of photo-generated carriers. Therefore, the power/energy density of the incident light, that is, light intensity may be inversely deduced using the voltage signal based on transverse Dember effect. When energy of the photons under light illumination is greater than the value of band gap of a material of the tilted epitaxial layer, the electron-hole pairs generated by the photons diffuse from the irradiated side to the other side along the tilted direction of the tilted epitaxial layer, and a value of the voltage signal is measured on the upper surface of the tilted epitaxial layer. The photodetector based on transverse Dember effect is calibrated using a laser with the same wavelength and different power, as well as a laser with the same power and different wavelengths. When the laser irradiates on the upper surface of the tilted epitaxial layer 2 of the photodetector based on transverse Dember effect, a voltage signal may be acquired via the voltage signal acquisition device 5. In this case, and the voltage signal and a corresponding laser wavelength and corresponding power may be recorded to complete the calibration. During actual use, a wavelength and intensity of incident laser and emergent laser may be tested according to the calibration results based on the voltage signal acquired via the photodetector based on transverse Dember effect. In the present disclosure, the photodetector prepared based on transverse Dember effect of the film can determine the wavelength and intensity of the laser based on the value of the transverse Dember voltage of the photodetector based on transverse Dember effect, without applying an external source. Therefore, operations are simple, an anti-interference capability is strong, and stability is good.

Further, the present disclosure further provides a method for preparing a transverse Dember effect-based photodetector. The method includes:

S1: Grow a tilted epitaxial layer 2 on a tilted single-crystal substrate 3 using a vapor deposition method, where there is an included angle α between a crystallographic axis c-axis and a surface normal N of the tilted epitaxial layer 2.

In some embodiments, a tilted single-crystal epitaxial film may be grown on the tilted single-crystal substrate 3 using a chemical vapor deposition method, and taken as the tilted epitaxial layer 2. The tilt angles of the tilted single-crystal substrate 3 and the tilted epitaxial layer 2 range from 0.1° to 45°. A thickness of the tilted epitaxial layer 2 is from 10 nm to 50,000 nm. In the present disclosure, the tilted epitaxial layer 2 is grown on the tilted single-crystal substrate 3, and the tilted epitaxial layer is only grown on the tilted single-crystal substrate. The voltage signal acquisition device 5 acquires the voltage signal generated based on the transverse Dember effect of the tilted epitaxial layer 2, and a main purpose of selecting the tilted single-crystal substrate 3 is to prepare the tilted single-crystal epitaxial film.

When the tilted epitaxial layer 2 is prepared, different thicknesses of the tilted epitaxial layer 2 may be implemented by controlling preparation time, and the thickness of the tilted epitaxial layer 2 is related to the response time. Therefore, ultra-fast under light illumination response can be implemented by adjusting the thickness of the tilted epitaxial layer 2.

S2: Prepare a patterned metal electrode pair 1 on an upper surface of the tilted epitaxial layer 2, where two metal electrodes of the patterned metal electrode pair 1 are located at two ends of the upper surface of the tilted epitaxial layer 2.

Specifically, the tilted single-crystal substrate 3 of the tilted epitaxial layer 2 is placed into a radio frequency magnetron sputtering device for vacuumization, and a patterned design is conducted via a mask plate, and the metal electrode pair 1 is sputtered on the upper surface of the tilted epitaxial layer 2.

S3: Connect each metal electrode to one end of a metal wire 4 via high temperature silver glue, and connect the other end of the metal wire 4 to a voltage signal acquisition device 5.

The following provides a specific embodiment of the method for preparing a transverse Dember effect-based photodetector of the present disclosure.

A 4H-SiC tilted epitaxial layer 2 is prepared on a high-quality n-type 4H-SiC tilted single-crystal substrate 3 at a position of the c-axis deflected by 4° in a <11-20> direction using a chemical vapor deposition (CVD), and a thickness of the tilted single-crystal substrate 3 is 30 μm. The <11-20> direction is a representation of a crystallographic orientation in a crystal, also known as a crystallographic index or a crystallographic marking. In 4H-SiC, the <11-20> direction is a specific crystallographic orientation in the crystal, describing arrangement of atoms in the lattice.

The 4H-SiC tilted single-crystal substrate 3 with the tilted epitaxial layer 2 is placed into the radio frequency magnetron sputtering device for vacuumization to 4×10⁻⁴ pa, a Ni metal film with a thickness of 50 nm is sputtered on an upper surface of the 4H-SiC tilted epitaxial layer 2 via a mask plate, to prepare the metal electrode pair 1. Sputtering power of the Ni metal film is 45 W, a sputtering duration is 60 s, a flow rate of argon is 40 sccm, and a working pressure is 0.4 Pa. A silver wire with a diameter of 0.1 mm is selected as the metal wire 4. The metal wire 4 is connected to the metal electrode pair 1 via a high-temperature-resistant silver glue, and one end of the metal wire 4 is crimped on the Ni metal electrode pair 1, to ensure normal operations of the photodetector based on transverse Dember effect in a high-temperature environment.

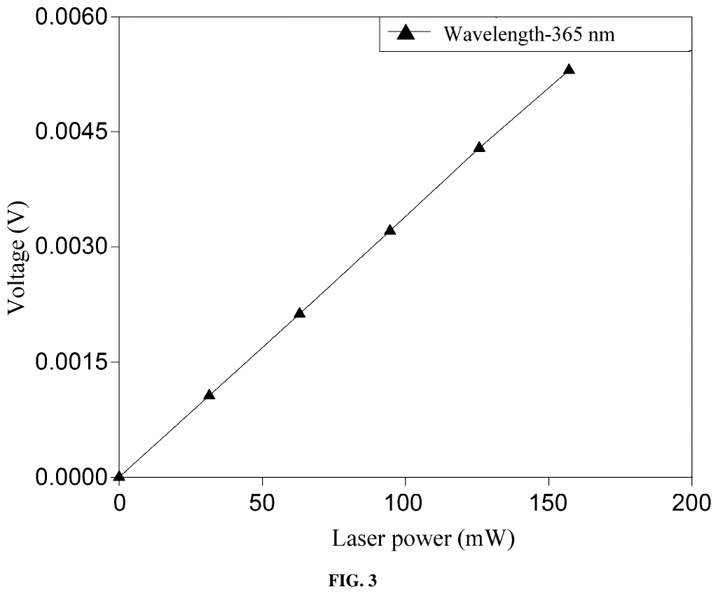

A voltage test for transverse Dember effect is conducted under light illumination with different intensity for a 4H-SiC-based passive photodetector. As shown in FIG. 3, under ultraviolet light with a wavelength of 365 nm, different light intensity/laser power corresponds to different voltage signal values. It can be learned from results shown in FIG. 3, there is a good linear relationship between the voltage signal output by the photodetector based on transverse Dember effect of the present disclosure and the laser power, and thus light intensity of the incident laser may be accurately determined based on the voltage signal.

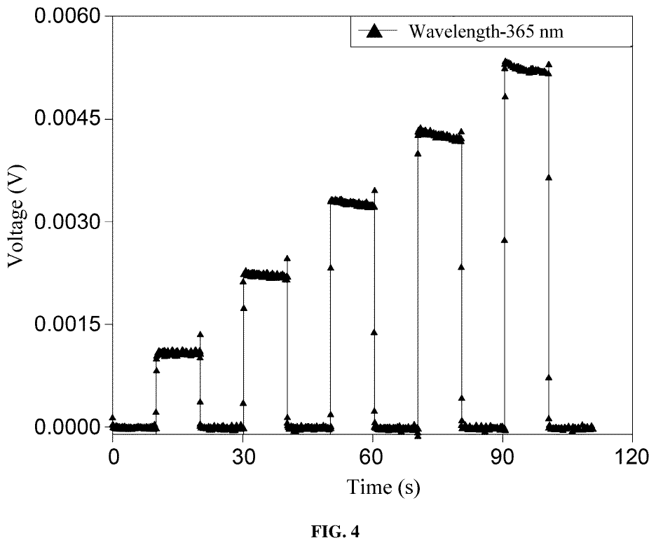

FIG. 4 shows response results, based on the 4H-SiC transverse Dember effect, of the photodetector based on transverse Dember effect of the present disclosure obtained under irradiation of the ultraviolet laser with different laser power and a wavelength of 365 nm. It can be learned from results shown in FIG. 4 that the photodetector based on transverse Dember effect of the present disclosure can output a stable voltage signal under irradiation of ultraviolet laser with different laser power.

Conventional photodetectors mainly include two types, namely, a diode-based photodetector and a photodetector based on transverse thermoelectric effect. The diode-based photodetector is a current-type device, and has poor anti-interference capability, while the photodetector based on transverse thermoelectric effect has low sensitivity and is greatly affected by the ambient temperature. Different from a working principle of the conventional photodetectors, in the present disclosure, passive photoelectric detection is implemented based on transverse Dember effect. The photodetector based on transverse Dember effect is a typical voltage-type device, and has high sensitivity. Due to transverse Dember effect, the voltage is generated based on mobility anisotropy of the electrons and the holes in the material, without an external electric field. This implements passive photoelectric detection.

In the present disclosure, the photodetector is prepared based on transverse Dember effect of the film for the first time, which resolves problems of existing photodetectors, for example, a bias voltage needs to be applied, operations are complex, the anti-interference capability is poor, sensitivity is poor, the existing photodetector is easy to be interfered with an environment, and stability is poor. In the present disclosure, the photodetector based on transverse Dember effect generates a voltage signal under light illumination. Compared with a current signal, stability is better; and compared with a voltage device based on transverse thermoelectric effect, sensitivity is higher. Therefore, photoelectric detection in a complex environment can be realized. In addition, the photodetector based on transverse Dember effect of the present disclosure can implement ultra-fast light illumination response by adjusting the thickness of the tilted epitaxial layer 2, which has a wide application prospect.

Particular examples are used herein for illustration of principles and implementation modes of the present disclosure. The descriptions of the above embodiments are merely used for assisting in understanding the method of the present disclosure and its core ideas. In addition, those of ordinary skill in the art can make various modifications in terms of particular implementation modes and the scope of application in accordance with the ideas of the present disclosure. In conclusion, the content of the description shall not be construed as limitations to the present disclosure.

What is claimed is:

1. A photodetector based on transverse Dember effect, comprising: a tilted single-crystal substrate, a tilted epitaxial layer, a metal electrode pair, metal wires, and a voltage signal acquisition device;
wherein, the tilted epitaxial layer is located on an upper surface of the tilted single-crystal substrate; a tilt angle of the epitaxial layer is an included angle between a crystallographic axis and a surface normal of the tilted epitaxial layer; two metal electrodes of the metal electrode pair are respectively located at two ends of an upper surface of the tilted epitaxial layer; each metal electrode is connected to one metal wire; the voltage signal acquisition device is configured to acquire voltage signals output by the two metal wires; and the voltage signals are generated by means of transverse Dember effect of the tilted epitaxial layer.

2. The photodetector based on transverse Dember effect according to claim 1, wherein the tilt angles range from 0.1° to 45°.

3. The photodetector based on transverse Dember effect according to claim 1, wherein a material of the tilted single-crystal substrate is AlN, Si₃N₄, or 4H-SiC.

4. The photodetector based on transverse Dember effect according to claim 1, wherein a material of the tilted epitaxial layer is Ga₂O₃, GaN, AlN, BN, B₄C, AlP, or 4H-SiC.

5. The photodetector based on transverse Dember effect according to claim 1, wherein a thickness of the tilted epitaxial layer is from 10 nm to 50,000 nm.

6. The photodetector based on transverse Dember effect according to claim 1, wherein a thickness of the metal electrode pair is from 50 nm to 200 nm; and a material of the metal electrode pair is W, Ag, Ti, Ni, or Pt.

7. The photodetector based on transverse Dember effect according to claim 1, wherein the metal wire is a high-purity metal wire.

8. A method for preparing a transverse Dember effect-based photodetector, comprising:
growing a tilted epitaxial layer on a tilted single-crystal substrate using a vapor deposition method, wherein there is an included angle between a crystallographic axis and a normal of the tilted epitaxial layer, and tilt angles of the tilted single-crystal substrate and the tilted epitaxial layer are close;
preparing a patterned metal electrode pair on an upper surface of the tilted epitaxial layer, wherein two metal electrodes of the patterned metal electrode pair are respectively located at two ends of the upper surface of the tilted epitaxial layer; and
connecting each metal electrode to one end of a metal wire via high temperature silver glue, and connecting the other end of the metal wire to a voltage signal acquisition device.

9. The method for preparing a transverse Dember effect-based photodetector according to claim 8, wherein the growing a tilted epitaxial layer on a tilted single-crystal substrate using a vapor deposition method specifically comprises:
growing a tilted single-crystal epitaxial film on the tilted single-crystal substrate using a chemical vapor deposition method, taking the tilted single-crystal epitaxial film as the tilted epitaxial layer, wherein a thickness of the tilted epitaxial layer is from 10 nm to 50,000 nm; and the tilt angle of the epitaxial layer ranges from 0.1° to 45°.

10. The method for preparing a transverse Dember effect-based photodetector according to claim 8, wherein the preparing a patterned metal electrode pair on an upper surface of the tilted epitaxial layer specifically comprises:
placing the tilted single-crystal substrate of the tilted epitaxial layer into a radio frequency magnetron sputtering device for vacuumization, and sputtering the patterned metal electrode pair on the upper surface of the tilted epitaxial layer in combination with a mask plate.
